(19) United States
(12) Patent Application Publication
(10) Pub. No.: US 2008/0242024 A1
(43) Pub. Date: Oct. 2, 2008

(54) METHOD OF MANUFACTURING SEMICONDUCTOR DEVICE

(75) Inventor: Shigeru SUGIOKA, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Chuo-ku (JP)

(21) Appl. No.: 12/050,664

(22) Filed: Mar. 18, 2008

(30) Foreign Application Priority Data
Mar. 27, 2007 (JP) 2007-081703

(51) Int. Cl. H01L 21/336

(52) U.S. Cl. 438/259; 257/E21.421

(57) ABSTRACT

To provide a semiconductor device using a Fin-FET and having a contact configuration such that the GIDL is reduced while limiting an increase in contact resistance, source and drain regions of the Fin-FET are formed by solid-phase diffusion positively utilizing impurity implantation after forming of contact holes 13 and oozing-out of an impurity from polysilicon contact plugs 14. Also, contact plugs 14 are extended to side surfaces of convex semiconductor layers 101a to form side wall portions 14a, thereby increasing the contact area.

This application is based upon and claims the benefit of priority from Japanese patent application No. 2007-081703, filed on Mar. 27, 2007, the disclosure of which is incorporated herein in its entirety by reference.

### BACKGROUND OF THE INVENTION

1. Field of the Invention

The present invention relates to a method of manufacturing a semiconductor device and, more particularly, to a method of manufacturing a semiconductor storage device using a fin field-effect transistor (hereinafter referred to as “Fin-FET”).

2. Related Art

With the progress in miniaturization of semiconductor elements, the impurity concentration in the channel region has been increased for the purpose of preventing punch-through in transistors. In the case of increasing the impurity concentration in the channel region in a selecting transistor used in the cell array of a dynamic random access memory (DRAM), however, an adverse effect of deteriorating the refreshing characteristic occurs by increasing the intensity of an electric field in the vicinity of the source-drain junction and, thereby increasing the junction leakage current. As a countermeasure against this problem, a technique of a recess-channel-array-transistor (RCAT) in which a gate length (L_{gate}) is made a longer by digging a substrate for reducing the impurity concentration in the channel region and improving the refreshing characteristic has been developed. This technique also has a problem that a reduction in ON current (Iₒₙ) and an increase in word line capacitance are caused due to an increase in channel resistance. It is probable that there is a difficulty in applying this technique to further miniaturization. To solve the problems of reduction in Iₒₙ and increase in word line capacitance, the development of fin cell array transistors is being pursued. Fin-FETs are of a double gate structure and have improved gate controllability in comparison with planar transistors. Also, in Fin-FETs, the channel region can be completely depleted by setting the gate width (W) narrower than twice the width of the depletion layer to obtain an advantageously low OFF current (I_{off}). Therefore, it is hoped that the Fin-FETs can be used as a completely depleted transistor having an improved sub-threshold characteristic.

An example of a DRAM using an MOS transistor having a fin structure in a cell array of the DRAM, such as disclosed in Japanese Patent Laid-Open No. 2002-18255, is known. According to this publication, a metal plug is used as a contact for a fin MOS transistor. With a metal plug, however, there is an anxiety that an increase in leakage current occurs due to a metallic contamination on the diffusion layer to deteriorate the refreshing characteristic. Under the present circumstances, therefore, a polysilicon-plug formed by filling a contact hole with polysilicon having a high content of phosphorus (P) is being used as a contact.

A conventional method of manufacturing a semiconductor memory device using such a Fin-FET will be described with reference to FIGS. 2 to 14. Also, FIG. 1A is a diagram showing a layout of a memory cell array of a DRAM using a Fin-FET; FIG. 1B is a partial enlarged view of the memory cell array; and FIG. 1C is a bird's-eye view of the structure of the Fin-FET. In the bird's-eye view, an insulating film above the gate electrode, a sidewall insulating film and a contact plug are not shown. Also in a bird's-eye view for the present invention, corresponding portions are not shown. In FIGS. 2 to 8, and 10 to 14, FIGS. 2A to 8A, and 10A to 14A show sections taken along line A-A in FIG. 1B; FIGS. 2B to 8B, and 10B to 14B, sections taken along line B-B in FIG. 1B; FIGS. 2C to 8C, and 10C to 14C, sections taken along line C-C in FIG. 1B; and FIGS. 2D to 8D, and 10D to 14D, sections taken along line D-D in FIG. 1B.

As shown in FIG. 2, pad oxide film 102 and field nitride film 103 are first formed successively on semiconductor substrate 101. Subsequently, as shown in FIG. 3, field nitride film 103 and pad oxide film 102 in places where isolation regions (shallow trench isolation (STI) regions) are formed are removed by etching using a lithography technique and a dry technique. Further, as shown in FIG. 4, trenches for embedding STI regions are formed in semiconductor substrate 101 by etching using a dry technique, with field nitride film 103 used as a mask. At this time, a portion of semiconductor substrate 101 surrounded by the trenches is formed by convex semiconductor layer 101a. Thereafter, the formed trenches are filled with an oxide film and isolation regions (STI) 104 are formed by using a chemical mechanical polishing (CMP) technique, with field nitride film 103 used as a stopper (FIG. 5). Thereafter, the height of the oxide film in isolation regions 104 is adjusted by wet processing for example. Subsequently, wet processing for removing field nitride film 103 is performed (FIG. 6). After removal of field nitride film 103, implantation of impurities to form a well and channel for transistors in the cell array region and the peripheral region is performed and a heat treatment for activation of the impurities is performed (not shown).

As described above, the Fin-FET has improved gate controllability in comparison with planar transistors. Therefore, channel doping for controlling threshold value is not performed on semiconductor substrate 101 or, even in a case where channel doping is performed, a p-type impurity is implanted at a low concentration, such that the concentration in the channel region does not exceed about 1.0×10¹⁸ cm⁻³. To form gate electrode diffusion-layer-side wall portions of the Fin-FET in the above-described structure, openings 105 are formed by performing patterning on resist 106 by a lithography technique as shown in FIG. 7. Thereafter, etching using a dry technique is performed to form slits 107, and resist 106 is removed by ashing (FIG. 8). FIG. 9A shows a top view of resist mask 106 formed as shown in FIG. 7, and FIG. 9B shows a top view after the step shown in FIG. 8 (after resist removal).

Subsequently, pad oxide film 102 is removed by wet processing and gate insulating film 108 is formed by oxidation. Polysilicon 109 for gate electrodes and silicon nitride film 110 to be used as a hard mask are thereafter formed successively (FIG. 10). At this time, slits 107 is also buried with polysilicon to form gate-electrode-side wall portions 109a. A gate electrode pattern is formed by a lithography technique and a dry technique (FIG. 11). After gate electrode forming, ion implantation is performed on convex semiconductor layer 101a to form lightly-doped-drain (LDD) regions for cell transistors (not shown). Thereafter, the same kind of insulating film as the hard mask used at the time of etching for the gate electrodes (silicon nitride film in this example) is formed on the entire wafer surface. The silicon nitride film previously formed is etched back by anisotropic etching. Silicon nitride film is thereby left on side surfaces of gate electrodes 109 to form side wall spacers 111 (FIG. 12). First interlayer insulating film 112 formed of a stack of boro-phospho-silicate glass (BPSG) film and tetra-ethyl-ortho-silicate (TEOS)-non-doped silicate glass (NSG) film is formed on the entire surface of the substrate (FIG. 13).

Cell contact holes 113 reaching an n-diffusion layer (not shown) on the convex semiconductor layer 101a are formed in interlayer insulating film 112. Implantation of phosphorus (P) and arsenic (As) is thereafter performed to form source regions and drain regions (n-type diffusion layers, not shown in the figures). Polysilicon film having a high content of P is deposited on first interlayer insulating film 112 and cell contact holes 113 are also filled with the polysilicon film. Subsequently, the polysilicon film on first interlayer insulating film 112 is removed by etching-back using a dry etching technique and by a CMP technique, thereby forming cell contact plugs 114 (FIG. 14).

Thereafter, source and drain regions and contacts of the peripheral transistors, and elements including bit lines, capacitors and wiring (Al, Cu) for applying voltages to all transistors and portions are formed by using a known method (not shown), thus enabling making of the DRAM using the Fin-FETs as cell array transistors.

Thus, in the related art, source and drain regions are formed according to LDD implantation and implantation of phosphorus and arsenic after forming of cell contact holes 113, and, in the case of using polysilicon having a high content of P at a high concentration in cell contact plugs 114, forming entails solid-phase diffusion from the polysilicon. In an actual DRAM manufacturing process, impurity diffusion such as oozing-out of P is not negligible because several steps including annealing for impurity activation in cell contact plugs 114 and a high-temperature heat treatment at the time of making capacitors exist after forming of cell contact plugs 114. In a case where an MOS transistor having fin structure is used as a selecting transistor (NMOS), if donor impurities such as phosphorus and arsenic are diffused to a position immediately below the gate electrode, there is an anxiety that the gate-induced dielectric leakage current (GIDL) is increased because the effective gate length is reduced and the area of contact between the gate electrode and a channel portion is increased relative to that in the planar structure. A method of reducing the phosphorus concentration to limit oozing-out of phosphorus from cell contact polysilicon plugs 114 is conceivable. However, this method has an adverse effect of increasing the resistance of the contact plug and reducing the ON current of the transistor.

Japanese Patent Laid-Open No. 2000-114486 discloses forming polysilicon plugs of a two-layer structure formed of a low-concentration polysilicon layer and a high-concentration polysilicon layer to limit oozing-out of phosphorus from the plugs in order to prevent the increase in leakage current.

In a case where Fin-FETs are used in a cell array, there is an anxiety that the GIDL is increased relative to that in the planar structure because the area of contact between the source and drain regions and the gate electrode is larger than that in the planar structure. There is a need to devise a method for reducing the GIDL in order to improve the refreshing characteristic.

Also, due to the structure of the Fin-FET, the desired ON current of the transistor can be maintained even if the gate width W is reduced. Therefore, miniaturization can progress. On the other hand, the next generation will come in which the width along the minor side of the convex semiconductor layer forming a diffusion layer is set to 50 to 30 nm to make a completely depleted device in which a channel region is completely depleted. In such a situation, there is a possibility of convex semiconductor layer 101a being thinner than the width of cell contact plug 114 as shown in FIG. 14B. In such a case, the contact area exists only on the upper surface of convex semiconductor layer 101a as indicated by 115 in FIG. 1C, and there is an anxiety that the contact resistance is increased. There is a need to study a contact forming method for reducing the contact resistance.

### SUMMARY OF THE INVENTION

An object of the present invention is to provide a semiconductor device using a Fin-FET and having such a contact shape as to limit the increase in contact resistance while reducing the GIDL.

It has been found that a method including digging contact plugs along side surfaces of convex semiconductor layer 101a, as shown in FIG. 15 or 17, and forming source and drain regions with an offset with respect to the gate electrode as shown in FIG. 19 by utilizing a combination of impurity implantation after forming contact holes and solid-phase diffusion from the contact plugs is effective in reducing the GIDL and improving the refreshing characteristic.

To achieve the above-described object, according to the present invention, there is provided a method of manufacturing a semiconductor device having a fin field effect transistor, the method including:

etching a semiconductor substrate to form convex semiconductor layers in the semiconductor substrate and trenches which separate the convex semiconductor layers from each other,

forming an isolation insulating film in the trenches separating the convex semiconductor layers,

forming slits for forming gate electrode side wall portions in the device at least in portions of the isolation insulating film along side surfaces of the convex semiconductor layers,

forming a gate insulating film on the surface of the convex semiconductor layer,

depositing a polysilicon layer for gate electrodes on the entire surface with filling the slits and forming the polysilicon layer into the shapes of the gate electrodes having side wall portions,

forming a side wall insulating film on the side walls of the gate electrodes,

forming an interlayer insulating film on the entire surface,

forming in the interlayer insulating film contact holes reaching the convex semiconductor layers and further digging portions of the isolation insulating film to expose at least an upper surface and opposite side surfaces of each convex semiconductor layer,

performing impurity implantation in portions of the convex semiconductor layers to be formed as source and drain regions through the contact holes,

filling the contact holes with amorphous silicon doped with an impurity, and

heating the device to cause solid-phase diffusion of the impurity from the amorphous silicon into the convex semiconductor layers for forming the source and drain regions and simultaneously forming contact plugs by converting the amorphous silicon into polysilicon.

According to the present invention, the source and drain regions of the semiconductor device having the Fin-FET are formed by positively utilizing implantation of impurities such as phosphorus and arsenic after forming of the contact holes and oozing-out of a phosphorus from the polysilicon contact plugs, thereby reducing diffusion of impurities such as phosphorus and arsenic immediately below the gate electrodes. The GIDL is thereby reduced to improve the refresh characteristic. Also, the contact plug is formed so as to contact not only the upper surface of the convex semiconductor layer but also side surfaces (two or three surfaces), thereby achieving a reduction in contact resistance.

### BRIEF DESCRIPTION OF THE DRAWINGS

FIG. 1A is a diagram showing a layout of a memory cell array in the related art and the present invention;

FIG. 1B is an enlarged view of a portion indicated the broken line a) in FIG. 1A;

FIG. 1C is a bird's-eye view of the Fin-FET in the related art seen in the direction of arrow in FIG. 1B;

FIGS. 2A to 2D are sectional views for explaining a process step of Fin-FET manufacturing methods in the related art and the present invention;

FIGS. 3A to 3D are sectional views for explaining a process step of Fin-FET manufacturing methods in the related art and the present invention;

FIGS. 4A to 4D are sectional views for explaining a process step of Fin-FET manufacturing methods in the related art and the present invention;

FIGS. 5A to 5D are sectional views for explaining a process step of Fin-FET manufacturing methods in the related art and the present invention;

FIGS. 6A to 6D are sectional views for explaining a process step of Fin-FET manufacturing methods in the related art and the present invention;

FIGS. 7A to 7D are sectional views for explaining a process step of Fin-FET manufacturing methods in the related art and the present invention;

FIGS. 8A to 8D are sectional views for explaining a process step of Fin-FET manufacturing methods in the related art and the present invention;

FIGS. 9A and 9B are plane views for explaining a process step of Fin-FET manufacturing methods in the related art and the present invention;

FIGS. 10A to 10D are sectional views for explaining a process step of Fin-FET manufacturing methods in the related art and the present invention;

FIGS. 11A to 11D are sectional views for explaining a process step of Fin-FET manufacturing methods in the related art and the present invention;

FIGS. 12A to 12D are sectional views for explaining a process step of Fin-FET manufacturing methods in the related art and the present invention;

FIGS. 13A to 13D are sectional views for explaining a process step of Fin-FET manufacturing methods in the related art and the present invention;

FIGS. 14A to 14D are sectional views for explaining a process step of Fin-FET manufacturing method in the related art;

FIGS. 15A to 15D are sectional views for explaining a process step of Fin-FET manufacturing method in the present invention;

FIGS. 16A and 16B are a schematic top view and a bird's-eye view, respectively, of the semiconductor device shown in FIG. 15;

FIGS. 17A to 17D are sectional views for explaining a process step of another Fin-FET manufacturing method in the present invention;

FIGS. 18A and 18B are a schematic top view and a bird's-eye view, respectively, of the semiconductor device shown in FIG. 17;

FIG. 19 is a schematic diagram showing the positions of the junctions of source and drain regions; and

FIG. 20 is a sectional view (C-C section) showing an example of the semiconductor device of the present invention after the completion of the process to forming of a capacitive plate of a capacitor.

### DETAILED DESCRIPTION OF THE PREFERRED EMBODIMENTS

Solving means according to the present invention for solving the problems of the related art will be described below.

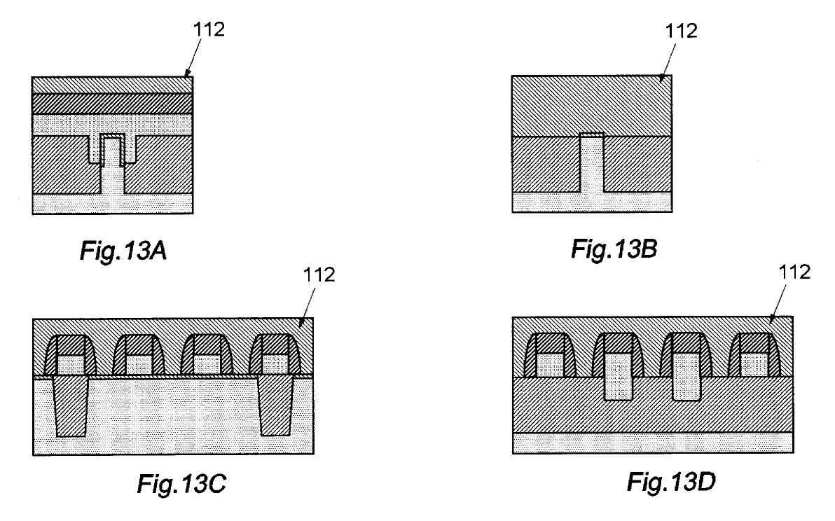

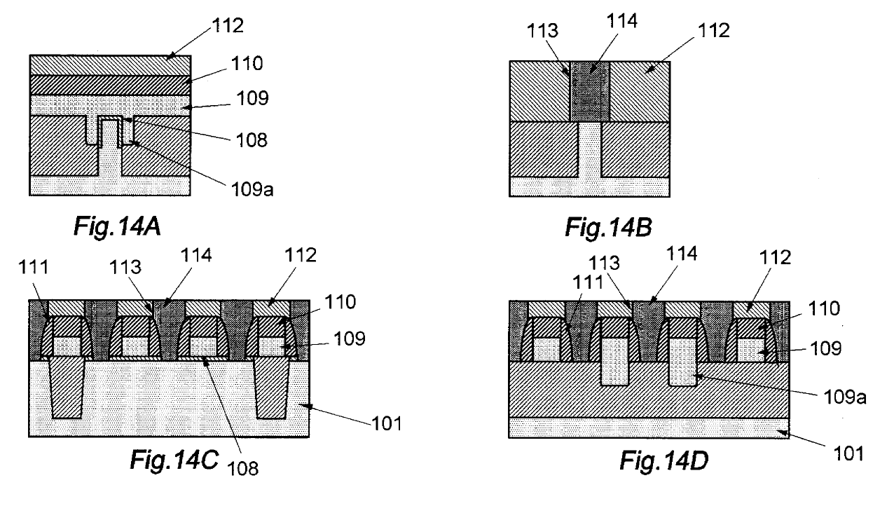

A process is performed which is substantially the same as the manufacturing method of the related art from the beginning to forming of first interlayer insulating film 112 shown in FIG. 13 except for implantation for forming an LDD region. Forming of cell contact holes 13 is thereafter performed. At this time, etching is performed so that the opening is downwardly extended along side surfaces of convex semiconductor layer 101a. The contact area can be increased in this way to reduce the contact resistance.

After forming contact holes 13, implantation of impurities as donors such as phosphorus and arsenic is performed for forming of source and drain regions, polysilicon having a high content of P is buried in the contact holes to form cell contact plugs 14. Several subsequent steps of processing at high temperatures of 700 to 1000° C., including a step for annealing for activation of impurities in the cell contact plugs and a step at the time of making capacitors, exist. The source and drain regions are formed by using solid-phase diffusion due to these steps. As a result, a reduction in the concentration of the impurities as donors such as phosphorus and arsenic immediately below the gates, i.e., a reduction in GIDL, can be expected.

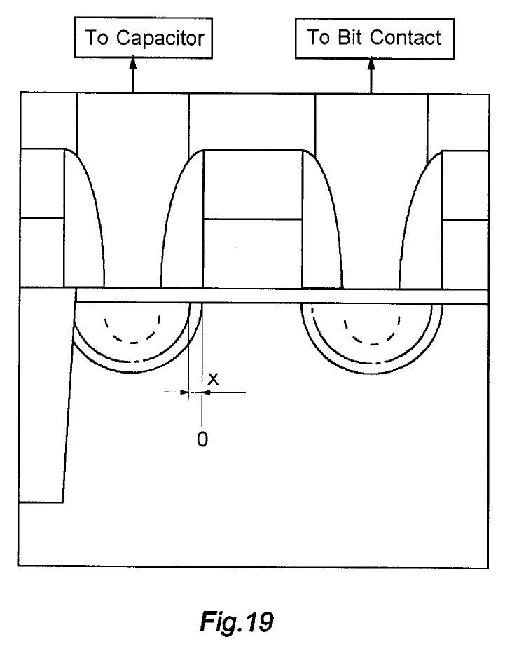

As described above, the cell contact holes are formed as to be downwardly extended along side surfaces of convex semiconductor layer 101a, and source and drain regions of an offset structure with respect to the gate electrode such as shown in FIG. 19 are formed by using implantation of impurities such as P and As after forming of contact holes and using oozing-out of phosphorus from the polysilicon plugs. A reduction in contact resistance and a reduction in GIDL can therefore be expected.

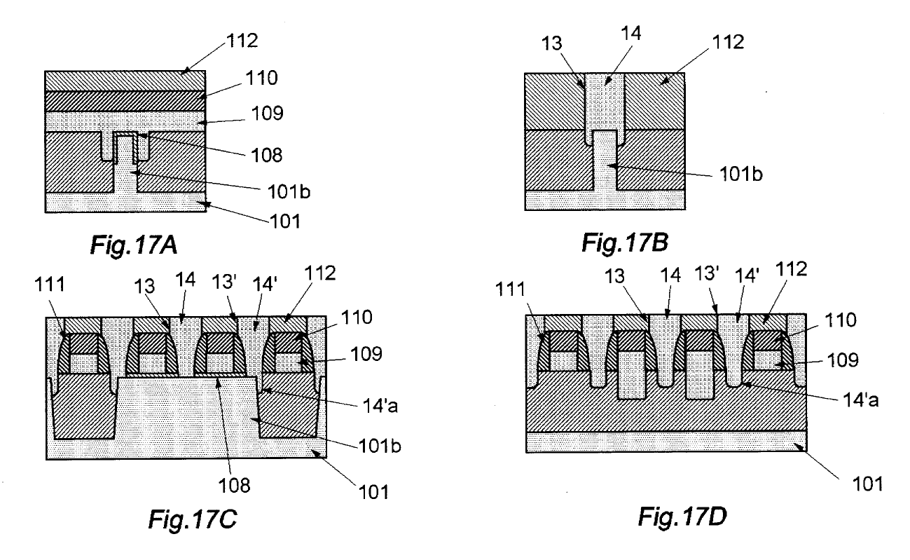

While in the above-described method cell contact plugs are formed for contact in three directions: one upper-surface direction and opposite-side-surface directions, the isolation insulating film may be dug by cutting the semiconductor layer on the storage node (SN) side, i.e., reducing the length of the semiconductor layer in the longitudinal direction during the formation of an isolation trench, so that the upper surface, the opposite side surfaces and the storage-node-side end surface are exposed on the storage node side as shown in FIG. 17 when the contact holes are formed. In this case, contact can be made in four directions: one upper-surface direction, two opposite-side-surface directions and one end-surface direction and a further reduction in contact resistance can be expected.

Here, diffusion of the impurities is controlled by adjusting the distance between the fin gate and the contact plug and the heat treatments. Also, because of anxiety about punch-through, it is desirable to avoid equality between the depth of the fin (the region of the convex semiconductor layer surrounded by the gate electrode side wall portions and the gate electrode lower surface) and the depth of the source and drain regions. To do so, the depth of contact is set smaller than the depth of the fin, i.e., the depth of the gate side wall portions.

Exemplary embodiments of the present invention will be concretely described below. The present invention, however, is not limited to the embodiments described below.

### First Exemplary Embodiment

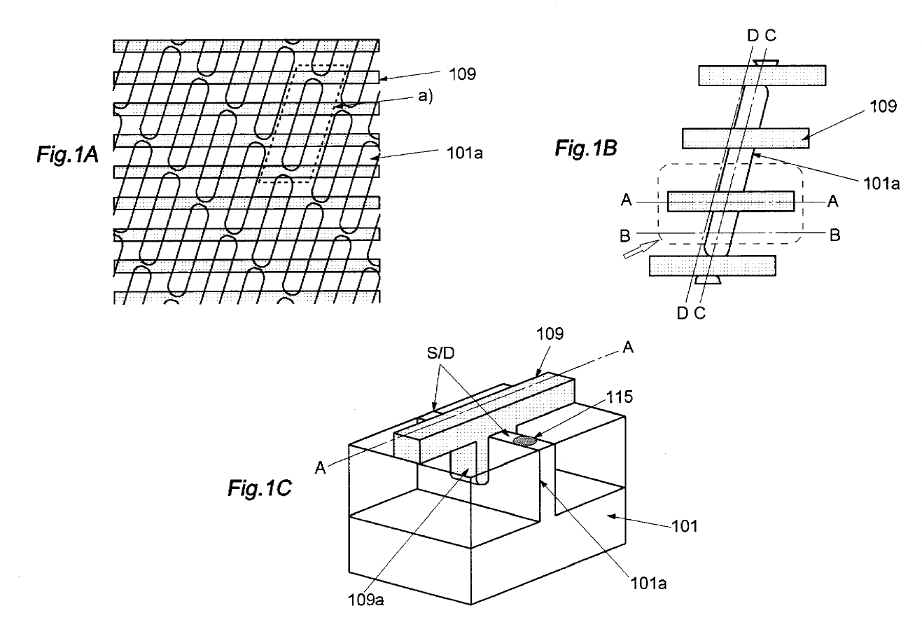

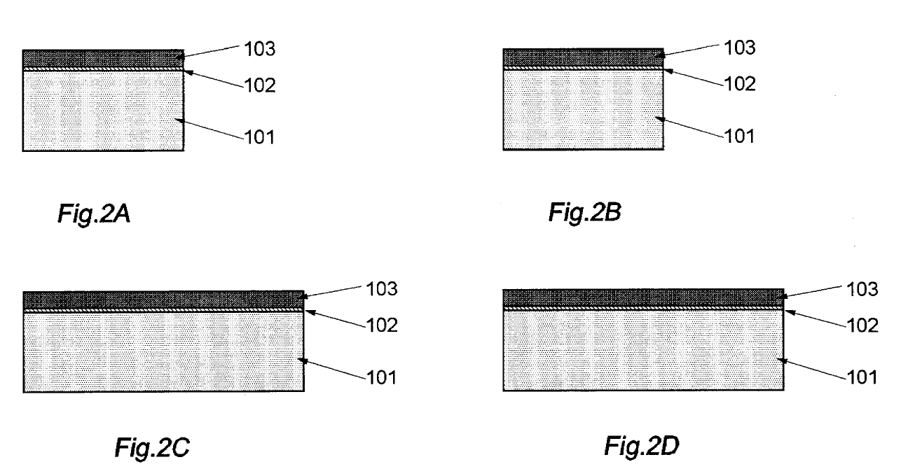

FIGS. 2 to 8, 10 to 13, and 15 are sectional views of a semiconductor device showing the process of forming a Fin-FET portion for explanation of a first exemplary embodiment of the manufacturing method in accordance with the present invention. FIGS. 2A to 8A, and 10A to 13A, and 15A show sections taken along line A-A in FIG. 1B; FIGS. 2B to 8B, 10B to 13B, and 15B, sections taken along line B-B in FIG. 1B; FIGS. 2C to 8C, 10C to 13C, and 15C, sections taken along line C-C in FIG. 1B; and FIGS. 2D to 8D, 10D to 13D, and 15D, sections taken along line D-D in FIG. 1B.

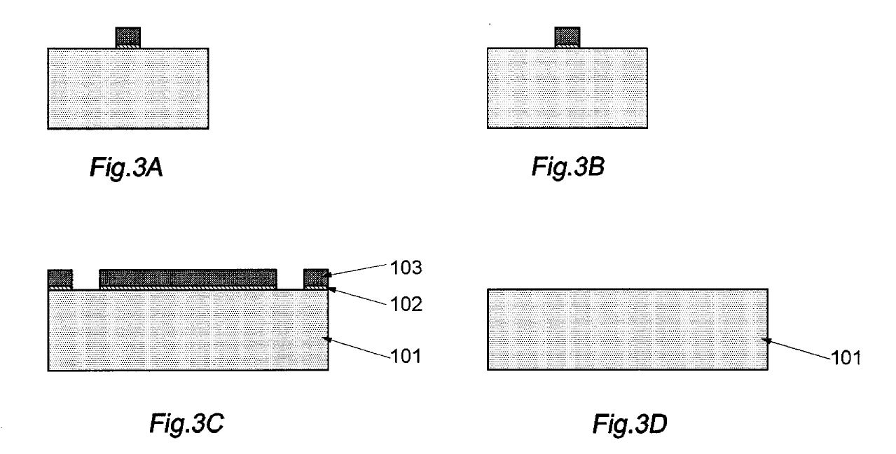

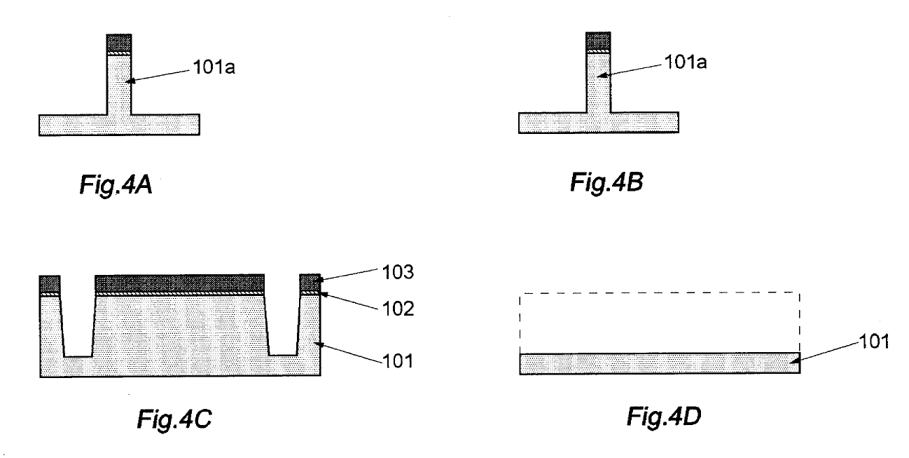

As shown in FIG. 2, pad oxide film 102 having a thickness of about 9 nm and field nitride film 103 having a thickness of about 120 nm are first formed successively on semiconductor substrate 101. This field nitride film 103 becomes a mask layer covering a diffusion layer and is also used as CMP stopper for an oxide film in which shallow trench isolation (STI) regions are embedded. Field nitride film 103 and pad oxide film 102 are patterned by using a lithography technique and a dry technique (FIG. 3). Further, Si etching to a depth of about 250 nm is performed by using a dry technique, with field nitride film 103 used as a mask (FIG. 4). At this time, field nitride film 103 is etched-back by about 50 nm.

In a case where a Fin-FET is used in a DRAM cell array, there is a need to set the diffusion layer width (in the minor-side direction of convex semiconductor layer 101a) to a target value of about 30 nm or less in order to realize miniaturization along the gate width direction and the completely depleted device using the Fin-FET. To realize this, slimming the field nitride film mask to about 60 nm or less by dry etching or wet etching is performed before Si etching and after patterning of the field nitride film. Then, Si etching is performed. The diffusion layer width is reduced to about 30 nm or less as a result of subsequent steps including an oxidation step.

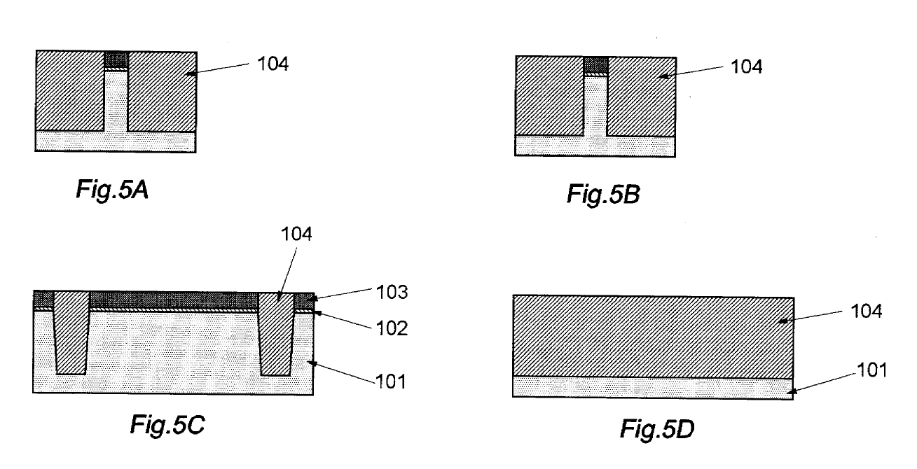

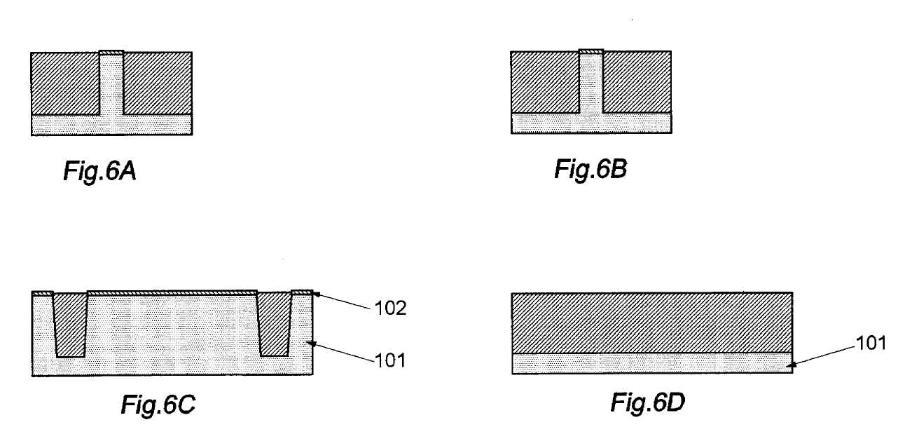

After Si etching, a silicon oxide film having a thickness of about 500 nm is formed on the entire surface by high density plasma-chemical vapor deposition (HDP-CVD). Thereafter, portions of silicon oxide film 104 to be formed as isolation regions are polished and removed by chemical mechanical polishing (CMP), with silicon nitride film 103 used as a stopper (FIG. 5). After CMP, oxide film wet etching for adjusting the height of the STI oxide film is performed and silicon nitride film 103 is removed by wet etching using hot phosphoric acid at about 160° C. Isolation regions (STI) 104 are thereby formed (FIG. 6).

Thereafter, implantation is performed for well forming and channel forming for transistors in the cell array region and the peripheral region, and a heat treatment for activation is performed (not shown). The Fin-FET has improved gate controllability in comparison with planar transistors. Therefore, channel doping for threshold value control is not performed on semiconductor substrate 101 or, even in a case where channel doping is performed, a p-type impurity is implanted at a low concentration, such that the concentration in the channel region does not exceed about 1.0×10¹⁸ cm⁻³.

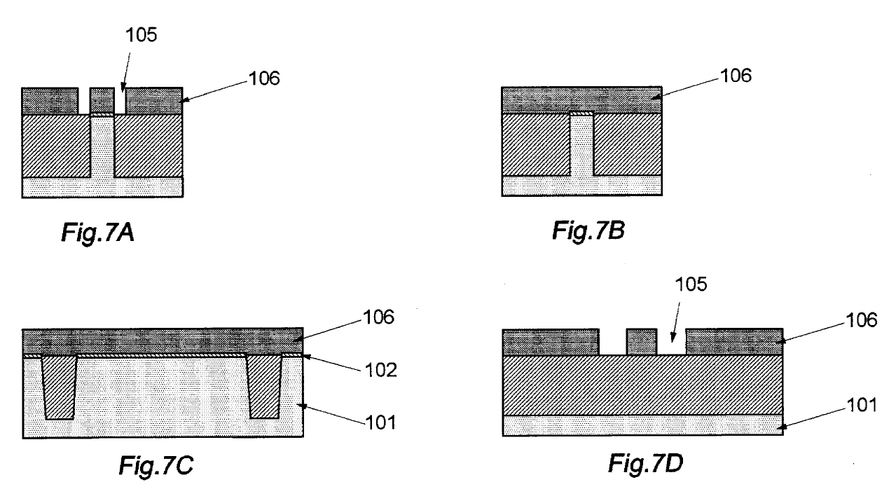

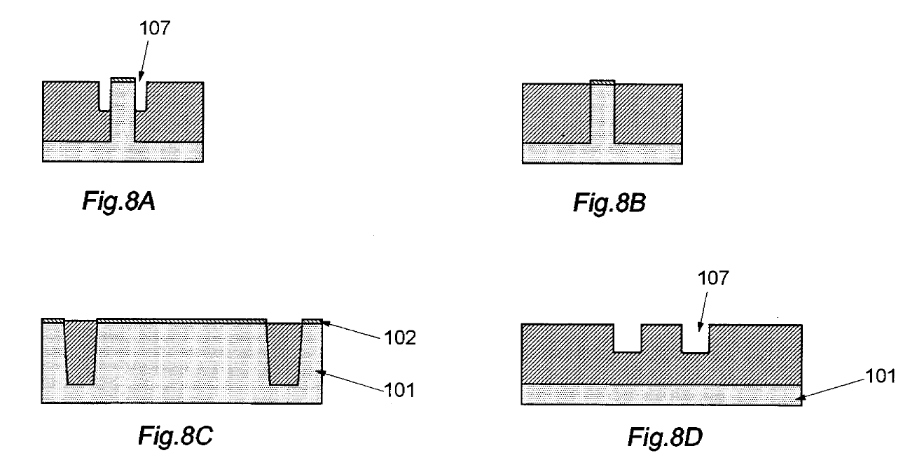

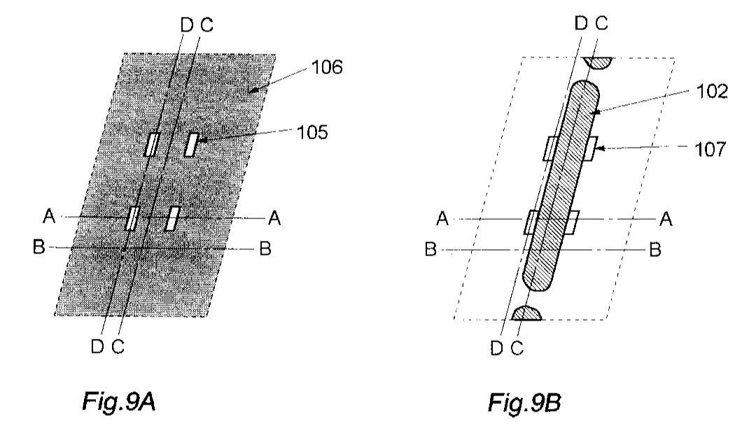

Subsequently, to form slits 107 of the Fin-FET in the aforementioned structure, openings 105 are formed by performing patterning on resist 106 as shown in FIG. 9A by a lithography technique (FIG. 7). Thereafter, etching of the oxide film is performed by a dry technique to form slits 107 having a depth of about 100 nm in isolation regions 104. Thereafter, resist 106 is removed by ashing (FIG. 8).

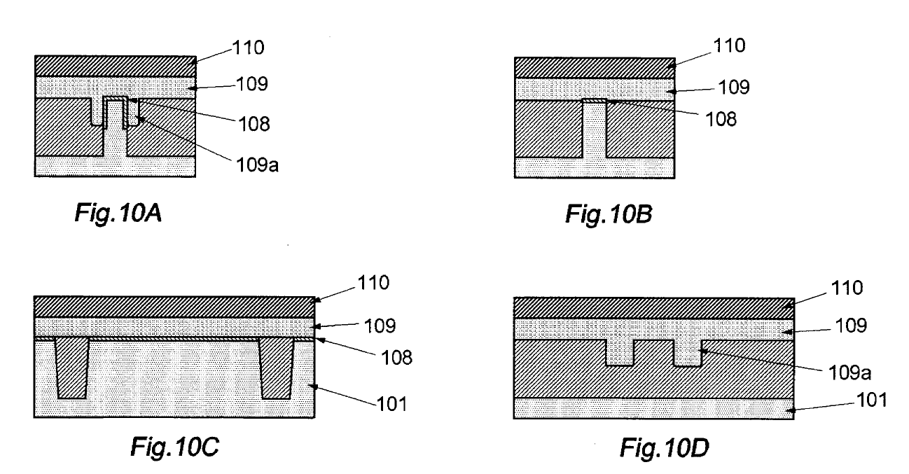

Subsequently, pad oxide film 102 remaining on the surface of semiconductor substrate 101 is removed by wet processing and thermal oxidation is performed to form gate insulating film 108 of a thickness of about 6 to 7 nm. Polysilicon 109 to be used as the gate electrode is formed to a thickness of about 70 nm. Either of polysilicon having a high phosphorus content and polysilicon having a high boron content may be provided. (In a case where polysilicon having a high boron content is used for the gate electrode, there is a need to add nitrogen to gate insulating film 108 by nitration). After film forming of polysilicon 109, implantation of boron for the channel region is performed. A condition for this implantation is 70 keV/8.0 E¹² cm⁻³. Thereafter, silicon nitride film 110 to be used as a hard mask is formed to a thickness of about 70 nm. While polysilicon is used as the gate electrode in this example, a multilayer gate electrode structure such as a polycide structure having a layer of silicide, e.g., WSi on polysilicon or a polymetal structure having a metal, e.g., W on polysilicon may be formed (FIG. 10).

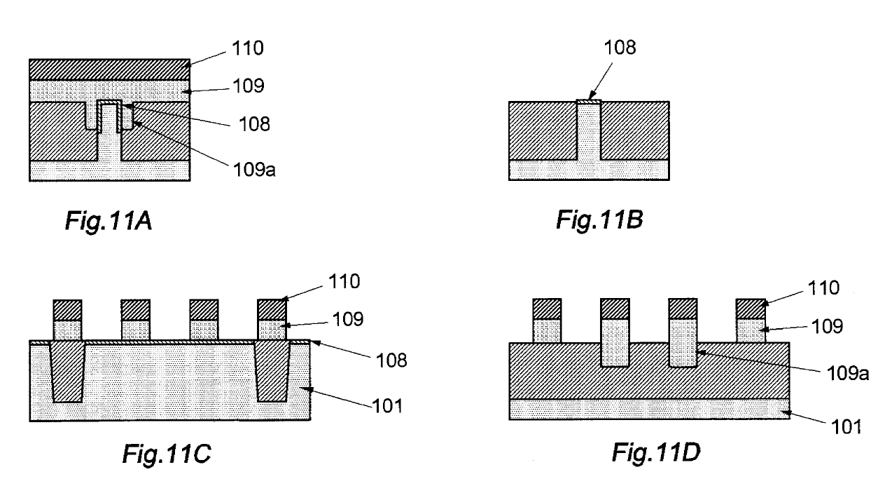

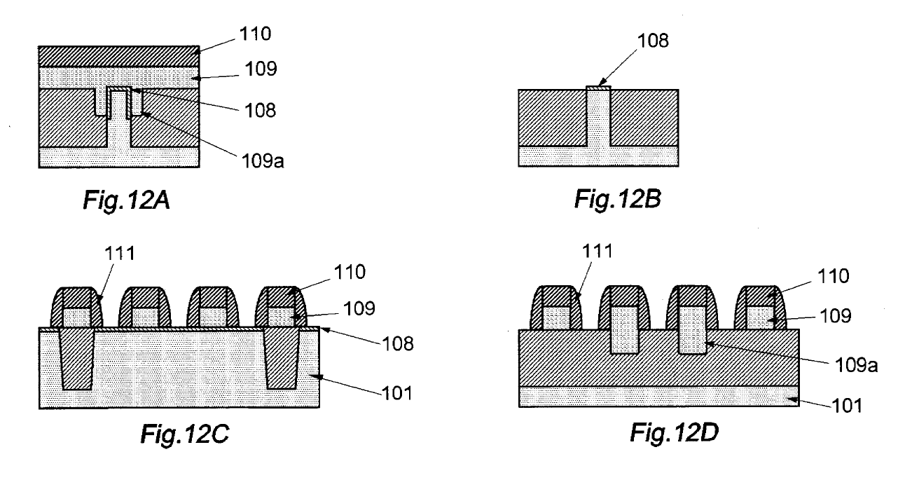

Thereafter, gate electrode patterning is performed by using a lithography technique and a dry technique (FIG. 11). Further, silicon nitride film is formed to a thickness of about 40 nm and etching-back is performed to form gate electrode side walls (SW) 111 (FIG. 12). Subsequently, BPSG film is formed to a thickness of about 600 to 700 nm on the entire surface by CVD and the surface of this BPSG film is made flat by reflow at 800° C. and a CMP technique. Subsequently, TEOS-NSG film is formed to a thickness of about 200 nm on this BPSG film, thereby forming a first interlayer insulating film 112 formed of BPSG film and TEOS-NSG film (FIG. 13).

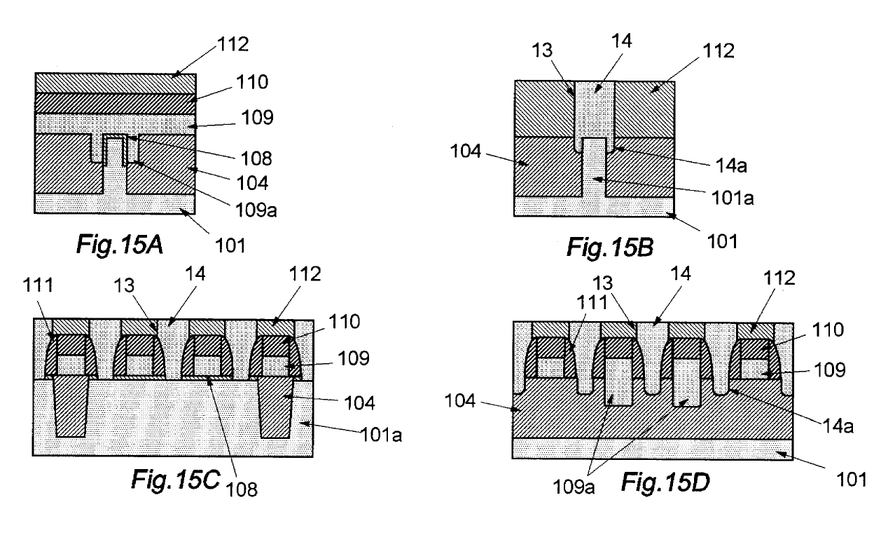

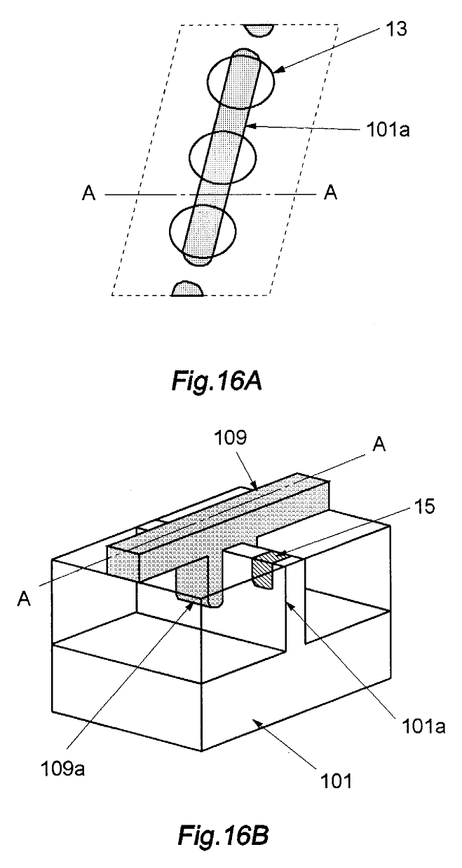

Thereafter, as shown in FIG. 15, cell contact holes 13 reaching the upper surface of semiconductor substrate 101 are formed as openings through first interlayer insulating film 112. Etching for forming cell contact holes 13 is not stopped when the diffusion layer is reached. Etching is further performed by about 20 to 30 nm so as to downwardly extend cell contact holes 13 along side surfaces of convex semiconductor layer 101a. The depth of etching along the side surfaces is set smaller than the depth of slits 107 in order to suppress punch-through. In this way, as shown in FIG. 16, contact 15 can be made in three directions: one upper-surface direction and two side-surface directions of the diffusion layer in convex semiconductor layer 101a to the upper surface of the diffusion layer and two directions. The contact area can be increased in this way and an increase in contact resistance can be expected.

After forming the cell contact plug holes, implantation of phosphorus and arsenic to a position shallower than the depth of slits 107 of the Fin-FET is performed to form source and drain electrodes (n-type diffusion layers, not shown in the figures). In this implantation, phosphorus is implanted in multiple steps for the purpose of limiting spreading in lateral directions and reducing the diffusion layer capacitance. Conditions for this phosphorous implantation are 20 keV/5.0 E¹² cm⁻³, 50 keV/2.4 E¹² cm⁻³, and 65 keV/6.0 E¹² cm⁻³. Arsenic is implanted at about 10 keV/1.0 E¹³ cm⁻³ to reduce the contact resistance.

After implantation, cell contact holes 13 are filled with amorphous silicon film doped with phosphorus. The amorphous silicon film is also deposited on first interlayer insulating film 12. Only the amorphous silicon film on first interlayer insulating film 12 is removed by etching-back using a dry etching technique and by a CMP technique. Cell contact plugs 14 having side wall portions 14a are thereby formed. The impurity concentration in the amorphous silicon film is 1.0×10²⁰ to 4.5×10²⁰ cm⁻³.

The DRAM manufacturing process includes several high-temperature processing steps after forming the cell contact plugs, including a heat treatment for converting the amorphous silicon film into polysilicon to reduce the resistance of the cell contact plugs and a step of processing at a high temperature of about 700 to 1000° C. at the time of making capacitors. An impurity profile such as shown in FIG. 19 is formed by positively utilizing oozing-out of P in the cell contact plugs due to these heat treatments. The donor impurity concentration below the gate can be reduced in this way and a reduction in GIDL can be expected.

Steps shown below exist as high-temperature heat treatment steps after forming of the cell contact plugs. Temperatures and times are shown as conditions for the high-temperature heat treatment steps.

| Step | Temp. | Time |
|---|---|---|
| Resistance-reducing annealing after forming of | 1000° C. | 10 sec. |
| the cell contact plugs: | | |
| Bake compaction nitrogen treatment on oxide | 700° C. | 10 min. |
| film to be formed as capacitor cores: | | |
| Annealing for doping HSG with P: | 700° C. | 30 min. |
| Nitrogen treatment on after forming of capacitor | 700° C. | 5 min. |
| insulating film for capacitors (forming on the HSG | | |
| surface): | | |

Note:
HSG is Hemi-Spherical Grain Silicon

FIG. 19 shows the positions of the junctions of the source and drain regions. Solid line A indicates a case where the amount of offset of the source and drain regions with respect to the gate electrode has the best ideal value 0 nm, and dot-dash line B indicates a case where the amount of offset of the source and drain regions with respect to the gate electrode is X nm. The broken line indicates the plug side wall portion seen in the D-D section. With approach to the cell contact plug, the value of X increases. If this amount of offset is excessively large, the corresponding region becomes a high-resistance portion to cause a reduction in Iₒₙ. If the amount of offset is minus, there is an anxiety that the GIDL is increased. Accordingly, it is thought that a suitable range of X is 0≦X≦5 nm.

If P oozes out excessively, it is effective to staking several layers of the film for the polyplug in order to suppress oozing-out. More specifically, for example, the first layer is formed to a thickness of 5 nm at a concentration of about 1.0×10¹⁹ cm⁻³, the second layer to a thickness of 150 nm at a concentration of about 4.4×10²⁰ cm⁻³, and the third layer to a thickness of 200 nm at a concentration of about 1.0×10²⁰ cm⁻³, followed by use of the same method as that described above. In this way, the Fin-FET having the desired impurity profile can be made while suppressing excessive oozing-out of P.

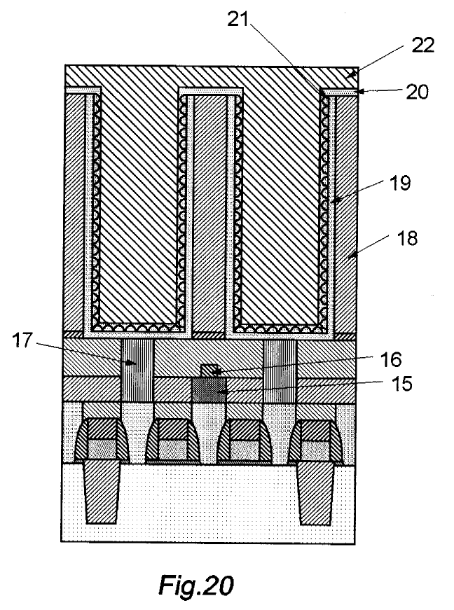

After the step shown in FIG. 16, the peripheral transistors and elements including bit lines, capacitors and wiring (Al, Cu) for applying voltages to contacts of all the transistors and portions are formed by using a known method (not shown), thus enabling making of the DRAM using the Fin-FETs as cell array transistors. FIG. 20 shows the structure in section after forming capacitors by way of example. Referring to FIG. 20, bit contact plug 15 to be connected to bit line 16 and capacitor contact plug 17 to be connected to a capacitor are formed on the SN side, and a cylindrical capacitor constituted by lower electrode polysilicon 19, capacitor insulating film 20 and upper electrode metal 22 is formed in a hole formed in core oxide film 18 for the capacitor. Also, HSG 21 is formed on the surface of lower electrode polysilicon 19 to secure the capacitor area.

### Second Exemplary Embodiment

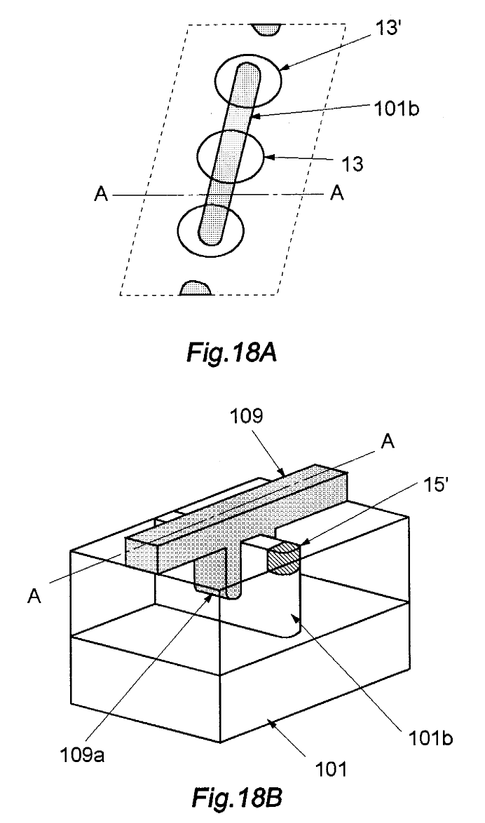

In the first exemplary embodiment, oxidation is performed after trench Si etching to form convex semiconductor layer 101b in which the length in the longitudinal direction, particularly the length of the SN portion is reduced, as shown in FIG. 17, thereby forming cell contact plug holes 13 in three directions: one upper-surface direction and two side-surface directions, and cell contact plug holes 13′ in four directions: one upper-surface direction and three side-surface directions. Thereafter, implantation of impurities, forming of plugs and solid-phase diffusion are performed, as in the first exemplary embodiment, thereby forming cell contacts 14 having side wall portions 14a and connected to bit lines between the gates and cell contacts 14′ having side wall portions 14a′ and connected to storage capacitors in the SN portion. As a result, contact surfaces 15′ can be taken in four directions for capacitor contact 14′ in the SN portion, as shown in FIG. 18B, and a further reduction in contact resistance can be expected.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A method of manufacturing a semiconductor device having a fin field effect transistor, the method comprising:
etching a semiconductor substrate to form convex semiconductor layers in the semiconductor substrate and trenches which separate the convex semiconductor layers from each other,
forming an isolation insulating film in the trenches separating the convex semiconductor layers,
forming slits for forming gate electrode side wall portions in the device at least in portions of the isolation insulating film along side surfaces of the convex semiconductor layers,
forming a gate insulating film on the surface of the convex semiconductor layer,
depositing a polysilicon layer for gate electrodes on the entire surface with filling the slits and forming the polysilicon layer into the shapes of the gate electrodes having side wall portions,
forming a side wall insulating film on the side walls of the gate electrodes,
forming an interlayer insulating film on the entire surface,
forming in the interlayer insulating film contact holes reaching the convex semiconductor layers and further digging portions of the isolation insulating film to expose at least an upper surface and opposite side surfaces of each convex semiconductor layer,
performing impurity implantation in portions of the convex semiconductor layers to be formed as source and drain regions through the contact holes,
filling the contact holes with amorphous silicon doped with an impurity, and
heating the device to cause solid-phase diffusion of the impurity from the amorphous silicon into the convex semiconductor layers for forming the source and drain regions and simultaneously forming contact plugs by converting the amorphous silicon into polysilicon.

2. The method of manufacturing a semiconductor device according to claim 1, wherein the fin field effect transistor is a memory cell transistor.

3. The method of manufacturing a semiconductor device according to claim 2, wherein the convex semiconductor layers are reduced in length in the longitudinal direction, and the isolation insulating film is dug at the time of forming the contact holes in a storage-node-side diffusion layer so that an upper surface, opposite side surfaces and a storage-node-side end surface of each convex semiconductor layer are exposed.

4. The method of manufacturing a semiconductor device according to claim 1, wherein when the contact holes are formed, the depth to which portions of the isolation insulating film are dug is smaller than the depth of the side wall portions of the gate electrodes.

5. The method of manufacturing a semiconductor device according to claim 1, wherein the impurity concentration in the amorphous silicon with which the contact holes are filled is 1.0×10²⁰ to 4.5×10²⁰ cm⁻³.

6. The method of manufacturing a semiconductor device according to claim 1, wherein the amount of offset X of the source and drain regions with respect to the gate electrodes is within a range of 0≦X≦5 nm.
